(19) United States
(12) Patent Application Publication
(10) Pub. No.: US 2004/0232806 A1
(43) Pub. Date: Nov. 25, 2004

(54) Piezoelectric transformer, power supply circuit and lighting unit using the same

(76) Inventors: Hiroshi Nakatsuka, Osaka-fu (JP); Katsu Takeda, Osaka-fu (JP)

Correspondence Address: RATNERPRESTIA, P O BOX 980, VALLEY FORGE, PA, 19482-0980, US

(21) Appl. No.: 10/844,244

(22) Filed: May 12, 2004

(30) Foreign Application Priority Data
May 16, 2003 (JP) P2003-138814

(51) Int. Cl. H01L 41/107

(52) U.S. Cl. 310/359

(57) ABSTRACT

A piezoelectric transformer includes a rectangular plate which is mainly made of piezoelectric material and in which a dimension in a longitudinal direction is larger than that in a width direction and a thickness direction is orthogonal to the longitudinal direction and the width direction. A low-impedance portion acting as one of a driving portion and a generator portion and a high-impedance portion acting as the other of the driving portion and the generator portion are provided in the rectangular plate so as to be arranged in the width direction such that the piezoelectric transformer is driven in a width-extensional vibration mode.

### BACKGROUND OF THE INVENTION

1. Field of the Invention

The present invention generally relates to a piezoelectric transformer and more particularly, to an improved piezoelectric transformer which is made compact and is capable of yielding a large output. The present invention also relates to a power supply circuit using the piezoelectric transformer and a lighting unit using the piezoelectric transformer.

2. Description of the Prior Art

In recent years, in order to make a power supply circuit of an electronic appliance compact, a piezoelectric transformer is used for a switching power supply. FIG. 25 is a schematic top plan view of a first known piezoelectric transformer utilizing a third-order radial extensional vibration mode, which has been proposed for use in applications for outputting large electric current in, for example, Japanese Patent Laid-Open Publication No. 4-167504 (1992). FIG. 26A is a sectional view taken along the line 26A-26A in FIG. 25, while FIGS. 26B and 26C show stress distribution and vibratory displacement distribution in the third-order radial extensional vibration mode in the known piezoelectric transformer of FIG. 25, respectively. Referring to these figures, a plurality of electrodes 14 are laminated in a thickness direction at a central portion of a piezoelectric ceramic disc 10 so as to form a high-impedance portion 12. An insulating annular portion 15 having no electrode is formed outside the high-impedance portion 12 and a low-impedance portion 11 in which a plurality of electrodes 13 are laminated in the thickness direction is further formed outside the insulating annular portion 15.

In order to impart piezoelectric property to the low-impedance portion 11 and the high-impedance portion 12, polarization operation is performed in the low-impedance portion 11 and the high-impedance portion 12. Supposing that the known piezoelectric transformer has electric input terminals a and b and electric output terminals c and d for voltage step-down purpose, the high-impedance portion 12 acts as a driving portion and the low-impedance portion 11 acts as a generator portion. In case an AC voltage is applied to the electric input terminals a and b, third-order radial extensional vibration is excited in the known piezoelectric transformer and a step-down voltage can be picked up from the electric output terminals c and d.

In the known piezoelectric transformer referred to above, if the number of lamination of the electrodes 14 in the high-impedance portion 12 located at the central portion of the piezoelectric ceramic disc 10 is increased to a level identical with that of the electrodes 13 in the low-impedance portion 11 located at an outer peripheral portion of the piezoelectric ceramic disc 10, electrical connection becomes difficult and thus, electrical connection structure becomes complicated disadvantageously. Therefore, in this known piezoelectric transformer, it is difficult to perform lamination of the electrodes 14.

In order to solve such a problem, a further piezoelectric transformer in which electrical connection and lamination of electrodes are easy is proposed in, for example, Japanese Patent Laid-Open Publication No. 11-145527 (1999). FIG. 27 is a top plan view of this second conventional piezoelectric transformer. FIGS. 28A is a sectional view taken along the line 28A-28A in FIG. 27, while FIGS. 28B and 28C show stress distribution and displacement distribution in a first-order contour extensional vibration mode in the conventional piezoelectric transformer of FIG. 27. As shown in FIG. 27, the conventional piezoelectric transformer includes a piezoelectric plate 20 which is formed into a square shape. The conventional piezoelectric transformer is divided into a driving portion 21 and a generator portion 22 in a thickness direction by an insulating portion 26. In each of the driving portion 21 and the generator portion 22, electrodes 25 and piezoelectric layers 29 are alternately laminated on each other. In order to impart piezoelectric property to the piezoelectric layers 29, polarization operation is performed in the piezoelectric layers 29. Polarization directions of neighboring ones of the piezoelectric layers 29 are opposite to each other as shown by the arrows in FIG. 28A. The electrodes 25 and the piezoelectric layers 29 are laminated by using known ceramic lamination technique.

In the driving portion 21, the electrode layers 25 are connected in every other place to an external electrode 23L on one of opposite outer sides of the piezoelectric plate 20 and the external electrode 23L is soldered to a terminal 24L. The remaining electrode layers 25 are connected to an external electrode 23R on the other of the opposite outer sides of the piezoelectric plate 20 and the external electrode 23R is soldered to a terminal 24R.

Similarly, in the generator portion 22, the electrode layers 25 are connected in every other place to an external electrode 27U on one of further opposite outer sides of the piezoelectric plate 20 and the external electrode 27U is soldered to a terminal 28U. The remaining electrode layers 25 are connected to an external electrode 27D on the other of the further opposite outer sides of the piezoelectric plate 20 and the external electrode 27D is soldered to a terminal 28D.

In the conventional piezoelectric transformer of FIG. 27, in case an AC voltage is applied to the driving portion 21, contour extensional vibration is excited and thus, a step-down AC voltage can be picked up from the generator portion 22.

As described above, the first known piezoelectric transformer of FIG. 25 has such disadvantages that its manufacture is difficult due to complicated electrical connection structure and difficult lamination of the electrodes.

On the other hand, the second conventional piezoelectric transformer of FIG. 27 can be manufactured easily by using known ceramic lamination technique. Meanwhile, since electrical connection is performed on the outer sides of the piezoelectric plate 20, electrical connection structure does not become complicated. However, since the external electrodes 23R, 23L, 27U and 27D are provided at portions having large vibratory displacement as shown in FIGS. 27 and 28C, efficiency drops inconveniently due to unreliable soldered portions and vibration loss.

### SUMMARY OF THE INVENTION

Accordingly, an essential object of the present invention is to provide, with a view to eliminating the above mentioned drawbacks of prior art, a piezoelectric transformer which is highly reliable and is capable of yielding a large output.

Another object of the present invention is to provide a piezoelectric transformer in which electrodes can be laminated easily.

Still another object of the present invention is to provide a piezoelectric transformer in which a high effective electromechanical coupling factor can be obtained.

A further object of the present invention is to provide a power supply circuit using such piezoelectric transformer.

A still further object of the present invention is to provide a lighting unit using such piezoelectric transformer.

In order to accomplish these objects of the present invention, a piezoelectric transformer of the present invention includes a rectangular plate which is mainly made of piezoelectric material and in which a dimension in a longitudinal direction is larger than that in a width direction and a thickness direction is orthogonal to the longitudinal direction and the width direction. A low-impedance portion acting as one of a driving portion and a generator portion and a high-impedance portion acting as the other of the driving portion and the generator portion are provided in the rectangular plate so as to be arranged in the width direction such that the piezoelectric transformer is driven in a width-extensional vibration mode.

### BRIEF DESCRIPTION OF THE DRAWINGS

These objects and features of the present invention will become apparent from the following description taken in conjunction with the preferred embodiments thereof with reference to the accompanying drawings in which:

FIG. 1 is a perspective view of a piezoelectric transformer according to a first embodiment of the present invention;

FIG. 2 is a sectional view taken along the line 2-2 in FIG. 1;

FIG. 3 is a top plan view of the piezoelectric transformer of FIG. 1;

FIG. 4 is a graph showing relation between ratio of length to width in a rectangular plate and effective electromechanical coupling factor keff in the piezoelectric transformer of FIG. 1;

FIG. 5 is a sectional view of a piezoelectric transformer which is a modification of the piezoelectric transformer of FIG. 1;

FIG. 6 is a top plan view of the piezoelectric transformer of FIG. 5;

FIGS. 7A and 7B are sectional views showing vibratory displacement in the piezoelectric transformer of FIG. 5 and the piezoelectric transformer of FIG. 1, respectively;

FIG. 8 is a perspective view of a piezoelectric transformer according to a second embodiment of the present invention;

FIG. 9 is a top plan view of the piezoelectric transformer of FIG. 8;

FIGS. 10A, 10B and 10C are sectional views taken along the lines 10A-10A, 10B-10B and 10C-10C in FIG. 8, respectively;

FIG. 11 is a graph showing relation between ratio of width of input electrode to overall width and electromechanical coupling characteristics in the piezoelectric transformer of FIG. 8;

FIG. 12 is a perspective view of a piezoelectric transformer according to a third embodiment of the present invention;

FIGS. 13A and 13B are sectional views taken along the lines 13A-13A and 13B-13B in FIG. 12, respectively;

FIG. 14 is a perspective view of a piezoelectric transformer which is a modification of the piezoelectric transformer of FIG. 12;

FIGS. 15A and 15B are sectional views taken along the lines 15A-15A and 15B-15B in FIG. 14, respectively;

FIG. 16 is a perspective view of a piezoelectric transformer according to a fourth embodiment of the present invention;

FIG. 17A is a sectional view taken along the line 17A-17A in FIG. 16 and FIGS. 17B, 17B and 17C are views showing vibratory displacement distribution, stress distribution and electric charge distribution in the piezoelectric transformer of FIG. 16, respectively;

FIG. 18 is a sectional view taken along the line 18-18 in FIG. 16;

FIG. 19 is a perspective view of a piezoelectric transformer according to a fifth embodiment of the present invention;

FIG. 20 is a sectional view of a piezoelectric transformer unit according to a seventh embodiment of the present invention;

FIG. 21 is a block diagram of a power supply circuit according to a seventh embodiment of the present invention;

FIG. 22 is a schematic front elevational of a liquid crystal display including a cold cathode tube type lighting unit acting as the power supply circuit of FIG. 21;

FIG. 23 is a block diagram of a power supply circuit according to an eighth embodiment of the present invention;

FIG. 24 is a block diagram of a power supply circuit according to a ninth embodiment of the present invention;

FIG. 25 is a schematic top plan view of a prior art piezoelectric transformer utilizing a third-order radial extensional vibration mode of a disc;

FIG. 26A is a sectional view taken along the line 26A-26A in FIG. 25 and FIGS. 26B and 26C are views showing stress distribution and vibratory displacement distribution in the prior art piezoelectric transformer of FIG. 25, respectively;

FIG. 27 is a top plan view of a further prior art piezoelectric transformer utilizing a first-order contour extensional vibration mode; and

FIG. 28A is a sectional view taken along the line 28A-28A in FIG. 27 and FIGS. 28B and 28C are views showing stress distribution and vibratory displacement distribution in the further prior art piezoelectric transformer of FIG. 27.

Before the description of the present invention proceeds, it is to be noted that like parts are designated by like reference numerals throughout several views of the accompanying drawings.

### DETAILED DESCRIPTION OF THE INVENTION

Hereinafter, embodiments of the present invention are described with reference to the drawings.

### FIRST EMBODIMENT

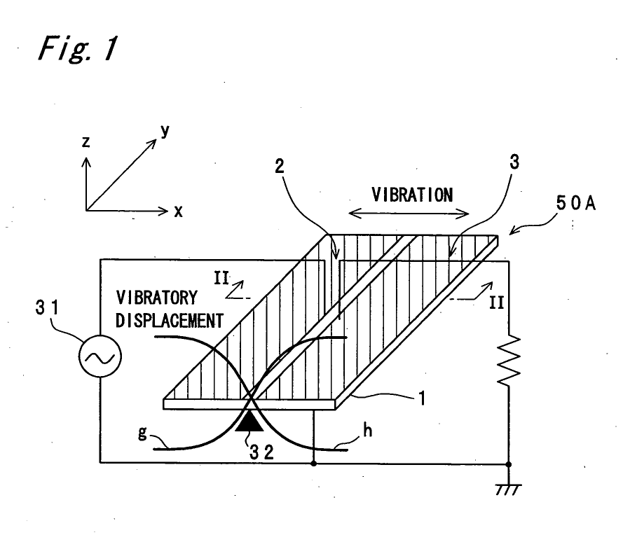

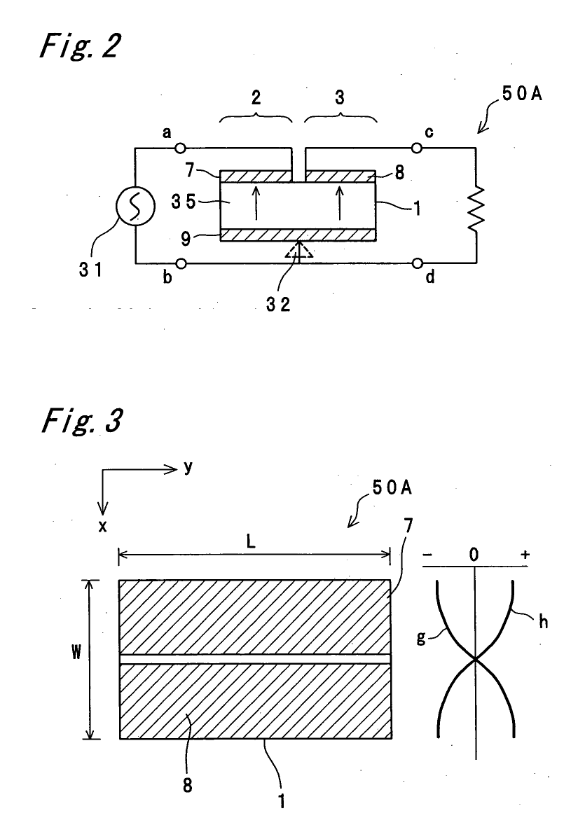

FIG. 1 is a perspective view of a piezoelectric transformer 50A according to a first embodiment of the present invention. FIG. 2 is a sectional view taken along the line 2-2 in FIG. 1 and FIG. 3 is a top plan view of the piezoelectric transformer 50A.

Referring to these figures, the piezoelectric transformer 50A includes a rectangular plate 1 which is mainly made of piezoelectric material. If rectangular coordinates having x-axis, y-axis and z-axis are set in FIG. 1, an x-axis direction, a y-axis direction and a z-axis direction correspond to a width direction, a longitudinal direction and a thickness direction of the rectangular plate 1, respectively. In the rectangular plate 1, a dimension in the longitudinal direction, i.e., the y-axis direction is larger than that in the width direction, i.e., the x-axis direction, while the thickness direction, i.e., the z-axis direction is orthogonal to the longitudinal direction, i.e. the y-axis direction and the width direction, i.e., the x-axis direction. In the rectangular plate 1, a ratio of a dimension L in the longitudinal direction (y-axis direction) to a dimension W in the width direction (x-axis direction), which are shown in FIG. 3, ranges from 1.08 to 1.65 as described later.

In the rectangular plate 1, a low-impedance portion 2 acting as one of a driving portion and a generator portion and a high-impedance portion 3 acting as the other of the driving portion and the generator portion are arranged in the width direction (x-axis direction). As shown in FIGS. 2 and 3, the low-impedance portion 2 includes an electrode 7 of the driving portion and a common electrode 9, while the high-impedance portion 3 includes an electrode 8 of the generator portion and the common electrode 9. A ratio between an impedance of the low-impedance portion 2 and that of the high-impedance portion 3 is adjusted by changing a ratio between an area of the electrode 7 of the driving portion and that of the electrode 8 of the generator portion.

In order to impart piezoelectric property to the rectangular plate 1, the rectangular plate 1 is polarized in the thickness direction. The arrows in FIG. 2 indicate a polarization direction of the rectangular plate 1. The polarization operation is performed by applying a strong electric field to the rectangular plate 1 and thus, electric dipoles in the rectangular plate 1 are arranged in a fixed direction. The rectangular plate 1 is formed by piezoelectric substance 35. A piezoelectric ceramic material such as lead zirconate titanate (PZT) is used as the piezoelectric substance 35. Meanwhile, piezoelectric single crystal which does not require polarization operation may also be used as the piezoelectric substance 35.

Then, operation of the piezoelectric transformer 50A is described. Supposing that “λ” denotes a wavelength, mechanical vibration is excited in a (λ/2) width-extensional vibration mode, i.e., a vibration mode of k31′ in the piezoelectric transformer 50A of FIGS. 1 to 3. More specifically, an AC voltage having a frequency close to a resonance frequency f determined by the width W of the rectangular plate 1 is applied between the electrode 7 of the driving portion and the common electrode 9 from input terminals a and b in FIG. 2 by an AC power supply 31. The resonance frequency f is calculated from the equation: (f=c/2 W) in which “c” denotes a sound velocity in the piezoelectric transformer 50A. As a result, longitudinal vibration is excited for expansion and contraction in the width direction of the piezoelectric transformer 50A.

Meanwhile, the vibration mode of k31′ represents a piezoelectric transverse effect longitudinal vibration mode in which an electric field is applied in the thickness direction so as to cause vibration in the width direction. This vibration mode of k31′ is distinguished from a vibration mode of k31 representing a piezoelectric transverse effect longitudinal vibration mode in which an electric field is applied in the thickness direction so as to cause vibration in the longitudinal direction. Here, the term “piezoelectric transverse effect” indicates an effect in which when an electric signal is applied in a polarization direction, distortion and stress are produced perpendicularly to the polarization direction.

A diagram at a right side of FIG. 3 shows displacement distribution in the width direction (x-axis direction) at a time point when the piezoelectric transformer 50A is subjected to vibration for expansion and contraction in the width direction in the (λ/2) longitudinal vibration mode. The rectangular plate 1 is vibrated in the width direction (x-axis direction) so as to repeat a vibrational configuration indicated by a curve g and a vibrational configuration indicated by a curve h. In the diagram of FIG. 3, if a “+” direction indicates rightward displacement of the piezoelectric transformer 50A in the width direction (x-axis direction) in FIG. 2, a “−” direction indicates leftward displacement of the piezoelectric transformer 50A in the width direction in FIG. 2. This mechanical vibration is converted into a voltage by piezoelectric effect and the converted AC voltage can be picked up from output terminals c and d. At this time, a ratio of the input voltage to the output voltage corresponds to a ratio of an impedance of the low-impedance portion 2 to that of the high-impedance portion 3. Here, this impedance ratio also corresponds to a ratio of an area of the electrode 7 of the driving portion to that of the electrode 8 of the generator portion.

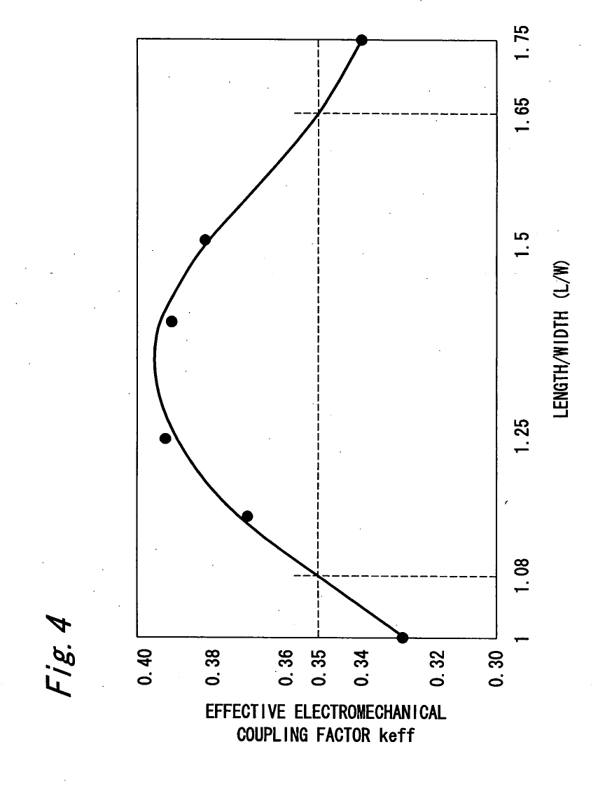

Then, result of investigation on change of effective electromechanical coupling factor keff relative to change of ratio of the length L to the width W in the rectangular plate 1 is described with reference to FIGS. 1 and 4. Here, the effective electromechanical coupling factor keff is explained. In a piezoelectric transformer, since an input portion and an output portion are formed in a single vibrator, a proportion of conversion of given electrical energy into elastic energy decreases. Thus, instead of an electromechanical coupling factor of the vibrator, namely, a proportion that electrical energy given to an ideal vibrator is converted into elastic energy, it is necessary to handle a coupling factor which is determined by a vibration mode and a structure. This coupling factor is defined as the effective electromechanical coupling factor keff in this specification.

FIG. 4 is a graph showing relation between ratio of the length L to the width W of the rectangular plate 1 and the effective electromechanical coupling factor keff. In the piezoelectric transformer 50A, the low-impedance portion 2 and the high-impedance portion 3 are formed in half regions of the rectangular plate 1, respectively. In FIG. 4, the solid line indicates maximum values of the effective electromechanical coupling factor keff at the time the piezoelectric transformer 50A of this embodiment is vibrated in the (λ/2) width-extensional vibration mode, i.e., the vibration mode of k31′. On the other hand, in case the piezoelectric transformer 50A is vibrated in a conventional (λ/2) lengthwise longitudinal vibration mode, the effective electromechanical coupling factor keff does not reach 0.35 as shown by the broken line in FIG. 4. As is clear from FIG. 4, if ratio of the length L to the width W of the rectangular plate 1 is so selected as to range from 1.08 to 1.65, the effective electromechanical coupling factor keff can exceed 0.35. Therefore, in order to obtain the high effective electromechanical coupling factor keff, it is preferable that ratio of the length L to the width W of the rectangular plate 1 should range from 1.08 to 1.65.

As described above, if the piezoelectric transformer 50A is driven in the width-extensional vibration mode, i.e., the vibration mode of k31′, it is possible to obtain the effective electromechanical coupling factor keff higher than that of drive of the piezoelectric transformer 50A in the lengthwise longitudinal vibration mode, i.e., a vibration mode of k31. This phenomenon can be construed as follows. If a vibration mode for exciting vibration is changed in an identical rectangular plate, easiness of vibration as a vibrator may change. According to a book entitled “Physical Acoustic-Principles and Methods” written by W. P. Mason, in case an identical rectangular plate is vibrated in the lengthwise longitudinal vibration mode and the width-extensional vibration mode, easiness of vibration may change. If the rectangular plate is vibrated in the lengthwise longitudinal vibration mode, the rectangular plate not only is vibrated in the longitudinal direction but is distorted in the width direction, so that vibrational energy is scattered in the width direction of the rectangular plate. On the other hand, if the rectangular plate is vibrated in the width-extensional vibration mode, the rectangular plate is vibrated in the width direction but is not distorted in the longitudinal direction, so that vibrational energy is not scattered in the longitudinal direction of the rectangular plate.

Therefore, if the rectangular plate is vibrated in the width-extensional vibration mode, it is possible to obtain the effective electromechanical coupling factor keff higher than that of a case in which the rectangular plate is vibrated in the lengthwise longitudinal vibration mode. If the effective electromechanical coupling factor keff is high, elastic energy can be effectively converted into electrical energy by piezoelectric effect. Meanwhile, inputted electrical energy can be converted into elastic energy by inverse piezoelectric effect. Hence, since electric power handled by a unit volume of the piezoelectric transformer, i.e., power density increases, a large output can be obtained and efficiency rises. Experiments conducted by the present inventors have revealed that output powers in the width-extensional vibration mode of this embodiment and the conventional lengthwise longitudinal vibration mode are 25 W and 10 W at an identical vibratory speed, respectively. A power density in the width-extensional vibration mode of this embodiment is 18 W/cc which is about 1.5 times 12 W/cc of the conventional lengthwise longitudinal vibration mode. Meanwhile, a current density in the width-extensional vibration mode of this embodiment is 90 mA/cm² which is about twice 40 mA/cm² of the conventional lengthwise extensional vibration mode.

Then, a support member 32 for supporting the piezoelectric transformer 50A is described by referring to FIGS. 1 to 3 again. The support member 32 supports the piezoelectric transformer 50A in the vicinity of a node of vibration of the rectangular plate 1 in the (λ/2) width-extensional vibration mode (first-order mode). Since the piezoelectric transformer 50A is supported in the vicinity of the node of vibration by the support member 32, the support member 32 supports and clamp the piezoelectric transformer 50A without hampering vibration.

Meanwhile, electrical connection in the low-impedance portion 2 and electrical connection in the high-impedance portion 3 are performed in the vicinity of the node of vibration of the rectangular plate 1 in the (λ/2) width-extensional vibration mode. Since the node of vibration does not vibrate, reliability of electrical connection in the piezoelectric transformer 50A is upgraded.

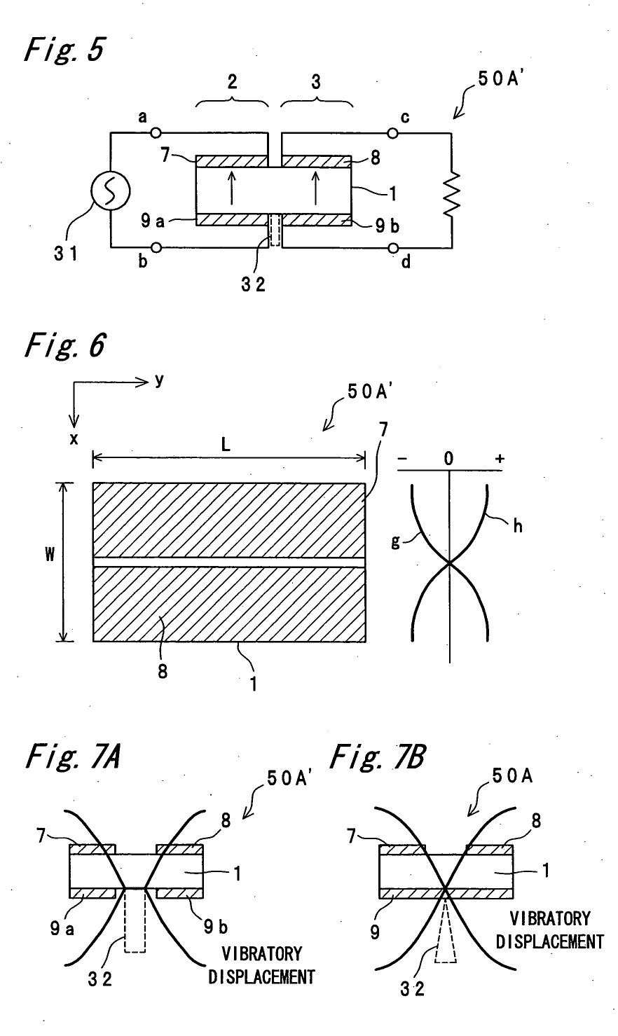

FIG. 5 shows a piezoelectric transformer 50A′ which is a modification of the piezoelectric transformer 50A. In the piezoelectric transformer 50A′, the lower common electrode 9 of the piezoelectric transformer 50A is divided into two electrically separated electrodes 9a and 9b which are spaced away from each other. The lower electrodes 9a and 9b are electrically separated from each other as described above. Thus, even if a noisy signal is introduced in between the electrode 7 of the driving portion and the electrode 9a, the noise is not picked up between the electrode 8 of the generator portion and the electrode 9b. Meanwhile, if the common electrode 9 is formed on a whole of the lower face of the rectangular plate 1 in the same manner as the piezoelectric transformer 50A, the node of vibratory displacement defines a point as shown in FIG. 7B. Thus, in this comparative example of FIG. 7B, when the support member 32 supports the piezoelectric transformer 50A without hampering vibration, the support member 32 should support the piezoelectric transformer 50A at the point defined by the node of vibration. Therefore, even if a contact area between the support member 32 and the rectangular plate 1 is increased only a little, vibration is hampered.

On the other hand, in FIG. 7A showing the piezoelectric transformer 50A′, since the common electrode 9 provided on the lower face of the rectangular plate 1 is divided into the electrodes 9a and 9b spaced away from each other, a node of vibratory displacement can be formed flat. Hence, since the support member 32 can be brought into contact with a flat portion formed by the node of vibratory displacement, a contact area between the support member 32 and the rectangular plate 1 can be increased, so that the support member 32 can support the piezoelectric transformer 50A′ stably without hampering vibration.

### SECOND EMBODIMENT

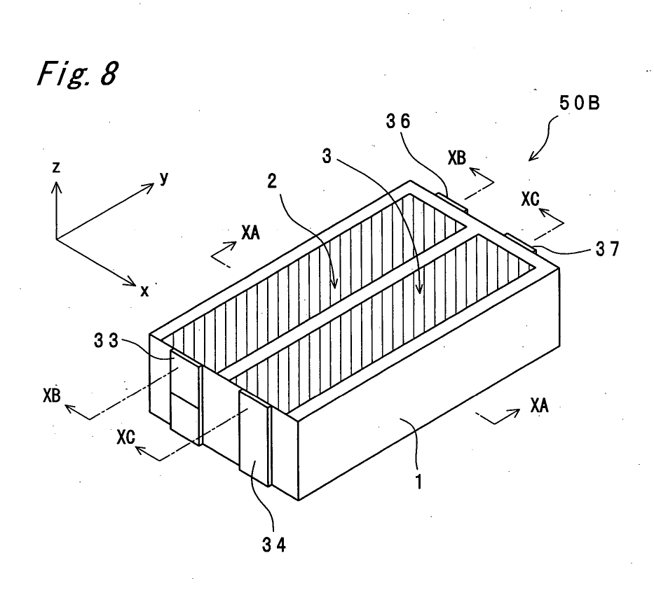

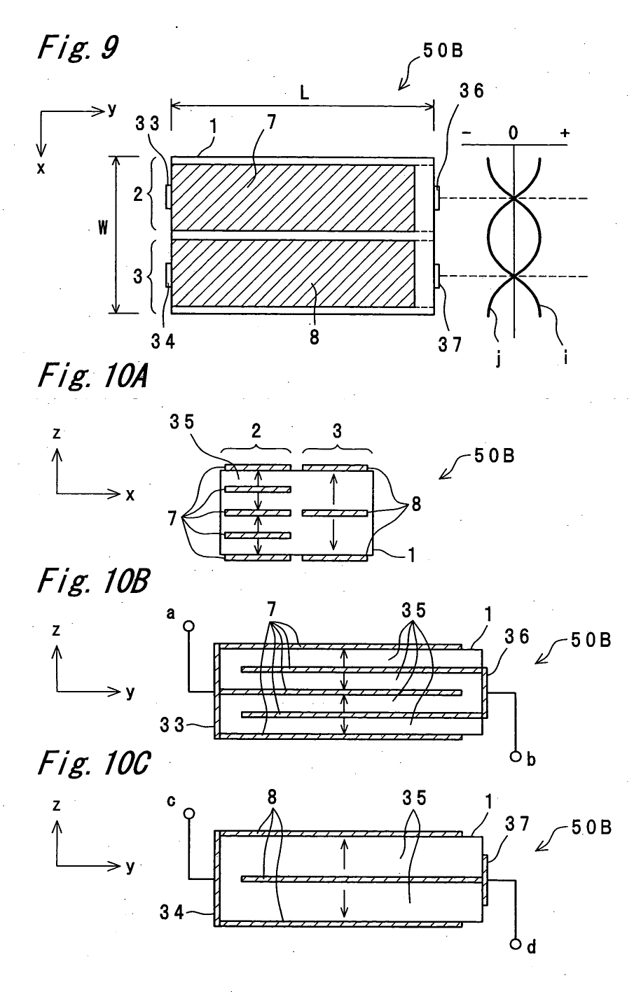

FIG. 8 is a perspective view of a piezoelectric transformer 50B according to a second embodiment of the present invention and FIG. 9 is a top plan view of the piezoelectric transformer 50B. FIGS. 10A, 10B and 10C are sectional views taken along the lines 10A-10A, 10B-10B and 10C-10C in FIG. 8, respectively. As shown in FIG. 9, the rectangular plate 1 of the piezoelectric transformer 50B also has the length L and the width W.

In the piezoelectric transformer 50B of this embodiment, the rectangular plate 1 is substantially bisected into first and second half regions in the width direction (x-axis direction). The low-impedance portion 2 is provided in the first half region of the rectangular plate 1, while the high-impedance portion 3 is provided in the second half region of the rectangular plate 1.

As shown in FIGS. 8 and 10B, in the low-impedance portion 2, electrode layers 7 and piezoelectric layers 35 are alternately laminated on each other in the thickness direction (z-axis direction) so as to form the driving portion. The electrode layers 7 are connected in every other place to a side electrode 33 on one of opposite side walls of the rectangular plate 1. The remaining electrode layers 7 are connected to a side electrode 36 on the other of the opposite side walls of the rectangular plate 1. The side electrodes 33 and 36 are, respectively, connected to terminals a and b.

Likewise, as shown in FIGS. 8 and 10C, in the high-impedance portion 3, electrode layers 8 and the piezoelectric layers 35 are alternately laminated on each other in the thickness direction (z-axis direction) so as to form the generator portion. The electrode layers 8 are connected in every other place to a side electrode 34 on the one of the above opposite side walls of the rectangular plate 1. The remaining electrode layer 8 is connected to a side electrode 37 on the other of the above opposite side walls of the rectangular plate 1. The side electrodes 34 and 37 are, respectively, connected to terminals c and d.

Thus, the side electrode 33 of the low-impedance portion 2 and the side electrode 34 of the high-impedance portion 3 are arranged in the width direction (x-axis direction) on the one of the opposite side walls of the rectangular plate 1, while the side electrode 36 of the low-impedance portion 2 and the side electrode 37 of the high-impedance portion 3 are arranged in the width direction (x-axis direction) on the other of the opposite side walls of the rectangular plate 1.

In order to impart piezoelectric property to the piezoelectric layers 35 in the rectangular plate 1, the piezoelectric layers 35 are polarized in the thickness direction (z-axis direction). The arrows in FIGS. 10A, 10B and 10C indicate polarization directions. In the driving portion and the generator portion, neighboring ones of the piezoelectric layers 35 in the thickness direction (z-axis direction) have polarization directions opposite to each other.

Then, operation of the piezoelectric transformer 50B of this embodiment is described. Referring to FIGS. 8 and 9, mechanical vibration is excited in a second-order width-extensional vibration mode, i.e., a vibration mode of k31′ in the piezoelectric transformer 50B. More specifically, an AC voltage having a frequency close to the resonance frequency f determined by the width W of the rectangular plate 1 is applied to the input terminals a and b in FIG. 10B. The resonance frequency f is calculated from the equation: (f=c/W) in which “c” denotes a sound velocity in the piezoelectric transformer 50B. As a result, longitudinal vibration is excited for expansion and contraction in the width direction of the piezoelectric transformer 50B.

A diagram at a right side of FIG. 9 shows displacement distribution in the width direction at a time point when the piezoelectric transformer 50B is subjected to vibration for expansion and contraction in the second-order width-extensional vibration mode. The rectangular plate 1 is vibrated in the width direction (x-axis direction) so as to repeat a vibrational configuration indicated by a curve i and a vibrational configuration indicated by a curve j. In the diagram of FIG. 9, if a “+” direction indicates rightward displacement of the piezoelectric transformer 50B in the width direction in FIG. 8, a “−” direction indicates leftward displacement of the piezoelectric transformer 50B in the width direction in FIG. 8. This mechanical vibration is converted into a voltage by piezoelectric effect and the converted AC voltage can be picked up from the output terminals c and d in FIG. 10C.

At this time, a ratio of the input voltage to the output voltage corresponds to a ratio of an impedance of the low-impedance portion 2 to that of the high-impedance portion 3. Here, the impedance of the low-impedance portion 2 depends on the number of lamination of the electrode layers 7 in the driving portion, while the impedance of the high-impedance portion 3 depends on the number of lamination of the electrode layers 8 in the generator portion.

In this embodiment, since the piezoelectric transformer 50B is vibrated in the width-extensional vibration mode, i.e., the vibration mode of k31′ in the same manner as the first embodiment, inputted electrical energy can be converted into elastic energy more effectively than a case of vibration in the lengthwise longitudinal vibration mode, i.e., the vibration mode of k31 and higher effective electromechanical coupling factor keff is obtained. Therefore, electric power handled by a unit volume of the piezoelectric transformer 50B, i.e., power density increases and thus, a large output can be obtained.

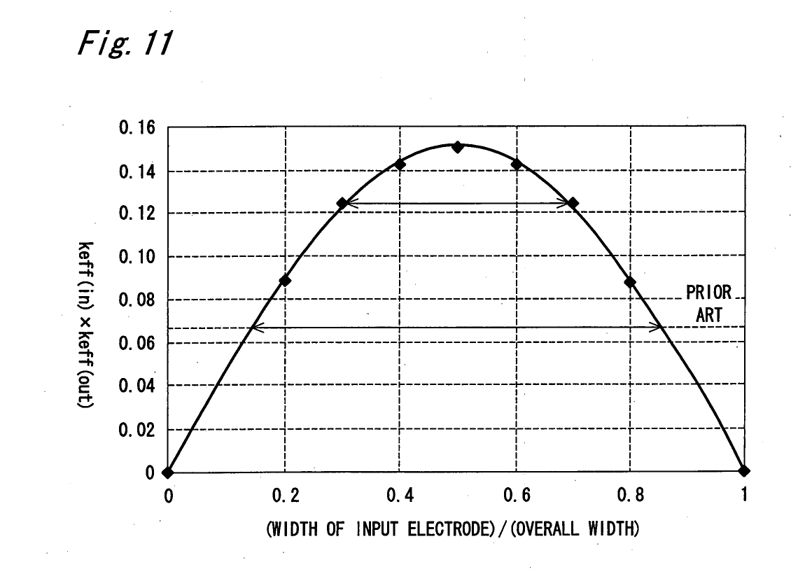

Meanwhile, in this embodiment, since the second-order width-extensional vibration mode is employed, amplitude of mechanical vibration of the piezoelectric transformer 50B becomes smaller than that of the firs-order mode, i.e., the (λ/2) width-extensional vibration mode and thus, elastic strain is restrained. Furthermore, since driving frequency rises, the number of vibrations per unit time increases and thus, the piezoelectric transformer 50B is capable of handling a large electric power. FIG. 11 is a graph showing relation between ratio of width of the input electrode to the overall width and electromechanical coupling characteristics in the piezoelectric transformer 50B. In FIG. 11, the abscissa axis represents ratio of width of the input electrode to the overall width in the piezoelectric transformer 50B, while the ordinate axis represents a product of the effective electromechanical coupling factor at the input side and the effective electromechanical coupling factor at the output side, namely, {keff(in)×keff(out)} as the electromechanical coupling characteristics. It is apparent from FIG. 11 that when the ratio of the width of the input electrode to the overall width of the piezoelectric transformer 50B ranges from 0.16 to 0.84, the electromechanical coupling characteristics {keff(in)×keff(out)} are larger than 0.066 of prior art and thus, a large output can be obtained.

In the driving portion, since the electrode layers 7 and the piezoelectric layers 35 are alternately laminated on each other and the electrode layers 7 are connected to each other in parallel, overall area of the electrode layers 7 increases. Furthermore, in the generator portion, since the electrode layers 8 and the piezoelectric layers 35 are alternately laminated on each other and the electrode layers 8 are connected to each other in parallel, overall area of the electrode layers 8 also increases. Therefore, the piezoelectric transformer 50B is capable of handling larger electric current.

Moreover, referring to FIG. 9, each of the lead-out electrodes 33, 34, 36 and 38 is disposed in the vicinity of a node of vibration of the rectangular plate 1 in the second-order width-extensional vibration mode and thus, is least likely to undergo influence of vibration. Therefore, reliability of electrical connection in the piezoelectric transformer is upgraded.

In this embodiment, the low-impedance portion 2 act as the driving portion and the high-impedance portion 3 acts as the generator portion by way of example. However, the low-impedance portion 2 and the high-impedance portion 3 may also act as the generator portion and the driving portion, respectively.

### THIRD EMBODIMENT

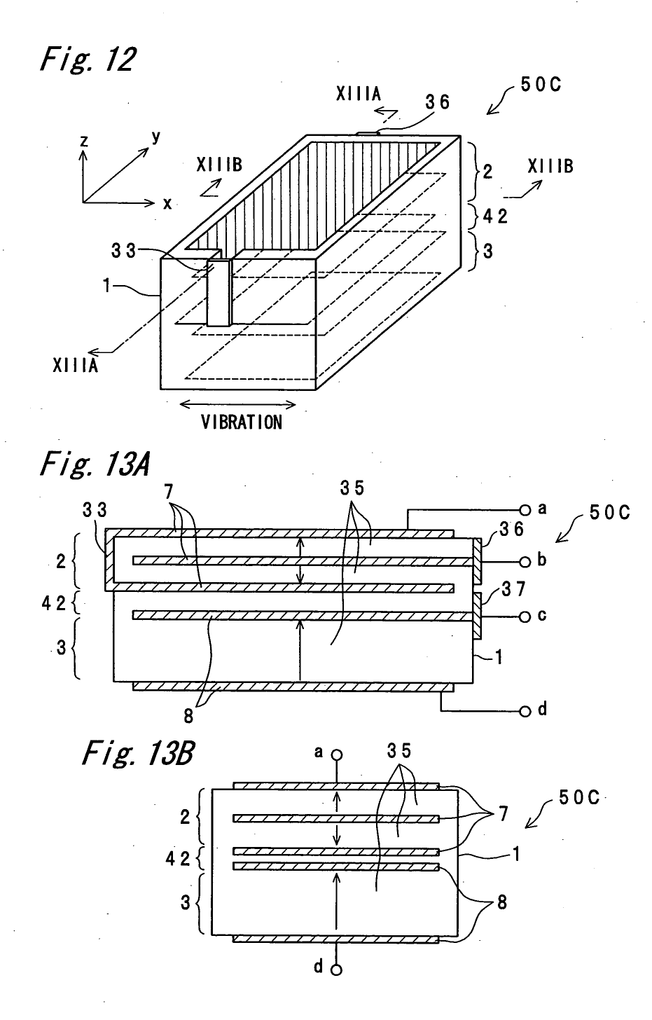

FIG. 12 is a perspective view of a piezoelectric transformer 50C according to a third embodiment of the present invention. FIGS. 13A and 13B are sectional views taken along the lines 13A-13A and 13B-13B in FIG. 12, respectively.

Referring to these figure, the piezoelectric transformer 50C includes the rectangular plate 1 which is mainly made of piezoelectric material. In the rectangular plate 1, a dimension the longitudinal direction, i.e., the y-axis direction is larger than that in the width direction, i.e., the x-axis direction, while the thickness direction, i.e., the z-axis direction is orthogonal to the longitudinal direction, i.e., the y-axis direction and the width direction, i.e., the x-axis direction. In the rectangular plate 1, a ratio of the dimension in the longitudinal direction (y-axis direction) to that in the width direction (x-axis direction) ranges from 1.08 to 1.65 as described before.

The rectangular plate 1 is divided in the thickness direction by an insulating portion 42 into the low-impedance portion 2 acting as one of the driving portion and the generator portion and the high-impedance portion 3 acting as the other of the driving portion and the generator portion such that the low-impedance portion 2 and the high-impedance portion 3 are laminated in the thickness direction of the rectangular plate 1.

In the low-impedance portion 2, the electrode layers 7 and the piezoelectric layers 35 are alternately laminated on each other in the thickness direction so as to form the driving portion. The electrode layers 7 are connected in every other place to the side electrode 33 on one of opposite side walls of the rectangular plate 1 and the side electrode 33 is connected to the terminal a. The remaining electrode layer 7 is connected to the side electrode 36 on the other of the opposite side walls of the rectangular plate 1 and the side electrode 36 is connected to the terminal b.

In the high-impedance portion 3, the number of lamination of the electrode layers is less than that of the low-impedance portion 2 and a pair of the electrode layers 8 interpose the piezoelectric layer 35 therebetween so as to form the generator portion. One of the electrode layers 8 is connected to the side electrode 37 on the other of the above opposite side walls of the rectangular plate 1 and the side electrode 37 is connected to the terminal c. The other of the electrode layers 8 is connected to the terminal d.

In order to impart piezoelectric property to the piezoelectric layers 35 in the rectangular plate 1, the piezoelectric layers 35 are polarized in the thickness direction (z-axis direction). The arrows in FIGS. 13A and 13B indicate polarization directions. In the low-impedance portion 2, neighboring ones of the piezoelectric layers 35 in the thickness direction (z-axis direction) have polarization directions opposite to each other.

The piezoelectric transformer 50C is driven in the (λ/2) width-extensional vibration mode, i.e., the first-order mode in the same manner as the piezoelectric transformer 50A of the first embodiment.

In this embodiment, since the piezoelectric transformer 50C is vibrated in the first-order width-extensional vibration mode, inputted electrical energy can be converted into elastic energy more effectively than a case of vibration in the lengthwise longitudinal vibration mode, i.e., the vibration mode of k31 and thus, higher effective electromechanical coupling factor keff is obtained. Therefore, electric power handled by a unit volume of the piezoelectric transformer 50C, i.e., power density increases and thus, a large output can be obtained.

Meanwhile, since the low-impedance portion 2 and the high-impedance portion 3 are laminated on each other in the thickness direction (z-axis direction) of the rectangular plate 1, the piezoelectric transformer 50C can be manufactured easily by known ceramic lamination technique. Furthermore, since the low-impedance portion 2 and the high-impedance portion 3 are laminated on each other in the thickness direction (z-axis direction) of the rectangular plate 1 while the length and the width of the rectangular plate 1 are secured, the width of the rectangular plate 1 can be designed with large allowance and area of the electrode can be increased for lower impedance while the effective electromechanical coupling factor is kept constant. As a result, the piezoelectric transformer 50C is applicable to a device requiring large electric current.

In this embodiment, the low-impedance portion 2 act as the driving portion and the high-impedance portion 3 acts as the generator portion by way of example. However, the low-impedance portion 2 and the high-impedance portion 3 may also act as the generator portion and the driving portion, respectively.

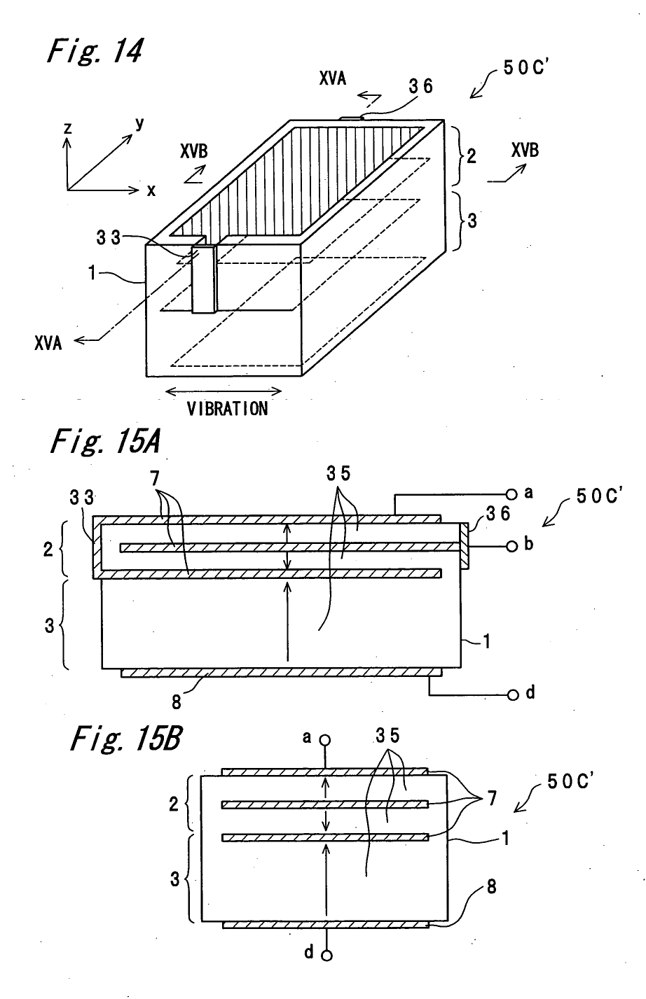

FIGS. 14, 15A and 15C show a piezoelectric transformer 50C′ which is a modification of the piezoelectric transformer 50C. The piezoelectric transformer 50C′ is different from the piezoelectric transformer 50C in the following point. Since other constructions of the piezoelectric transformer 50C′ are similar to those of the piezoelectric transformer 50C, the description is abbreviated for the sake of brevity.

In the piezoelectric transformer 50C′, the insulating portion 42 is not provided between the low-impedance portion 2 and the high-impedance portion 3 in contrast with the piezoelectric transformer 50C. In the low-impedance portion 2, the electrode layers 7 and the piezoelectric layers 35 are alternately laminated on each other so as to form the driving portion. In the high-impedance portion 8, the electrode layer 7 and the electrode layer 8 interpose the piezoelectric layer 35 therebetween so as to form the generator portion. Namely, in the piezoelectric transformer 50C′, the electrode layer 7 is used as a common electrode. The terminals a and be are used for the driving portion, while the terminals a and d are used for the generator portion. By using the above described arrangement, the piezoelectric transformer 50C′ is simplified structurally.

Meanwhile, also in the piezoelectric transformer 50C′, the low-impedance portion 2 and the high-impedance portion 3 may act as the generator portion and the driving portion, respectively.

### FOURTH EMBODIMENT

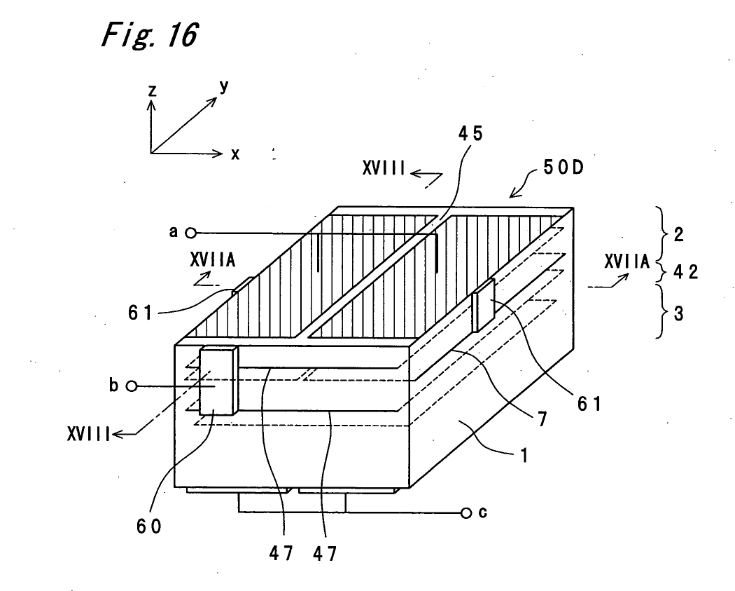

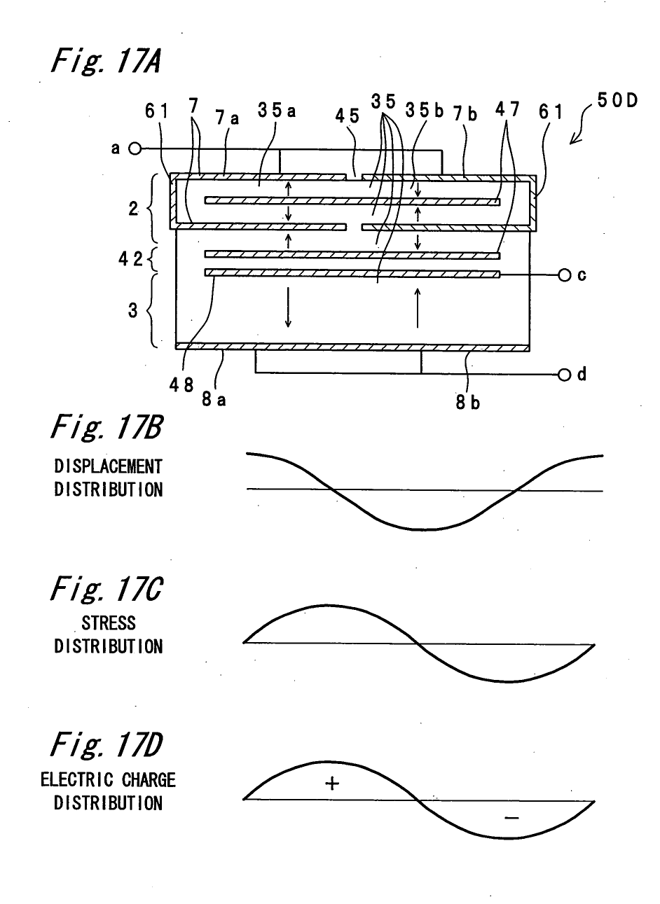

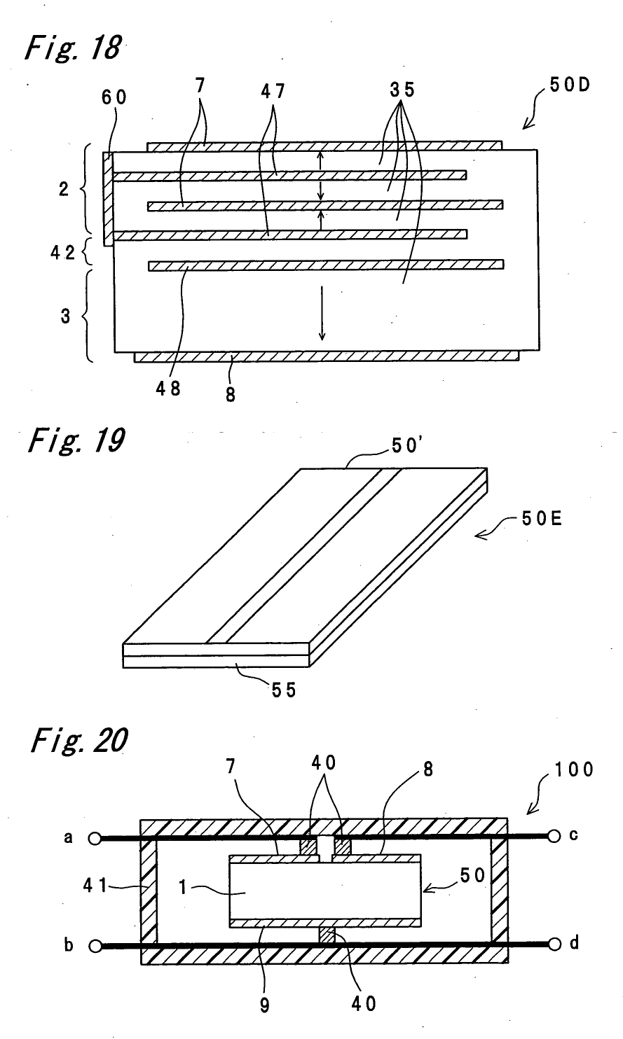

FIG. 16 is a perspective view of a piezoelectric transformer 50D according to a fourth embodiment of the present invention. FIG. 17A is a sectional view taken along the line 17A-17A in FIG. 16, while FIGS. 17B, 17C and 17D show displacement distribution, stress distribution and electric charge distribution in vibration of the piezoelectric transformer 50D. FIG. 18 is a sectional view taken along the line 18-18 in FIG. 16.

In the same manner as the piezoelectric transformer 50A of the first embodiment, the piezoelectric transformer 50D of this embodiment includes the rectangular plate 1 mainly made of piezoelectric material and the length of the rectangular plate 1 is larger than the width of the rectangular plate 1 such that the ratio of the length to the width in the rectangular plate 1 ranges from 1.08 to 1.65.

The piezoelectric transformer 50D of this embodiment is different from the piezoelectric transformer 50C of the third embodiment in that the piezoelectric transformer 50D is driven in the second-order width-extensional vibration mode in contrast with drive of the piezoelectric transformer 50C in the first-order width-extensional vibration mode. Hence, the piezoelectric transformer 50D is structurally different from the piezoelectric transformer 50C of the third embodiment slightly as follows. As shown in FIGS. 16 to 18, the piezoelectric transformer 50D includes the low-impedance portion 2 and the high-impedance portion 3 and the low-impedance portion 2 and the high-impedance portion 3 are separated from each other by the insulating portion 42. In the low-impedance portion 2, the first electrode layers 7 and second electrode layers 47 are alternately laminated on each other through the piezoelectric layers 35 in the thickness direction. The electrode layers 7 are electrically connected to the first terminal a acting as an electric current input-output port for the low-impedance portion 2, while the electrode layers 47 are connected to the second terminal b acting as a further electric current input-output port for the low-impedance portion 2. The laminated first electrode layers 7 are connected to a side electrode 61 formed on each of opposite side walls of the rectangular plate 1, while the second electrode layers 47 are connected to a side electrode 60 formed on one of further opposite side walls of the rectangular plate 1. The side electrode 60 is disposed in the vicinity of a node of vibration of the piezoelectric transformer 50D in the second-order width-extensional vibration mode.

At least each of the first electrode layers 7 is divided in the width direction into two portions 7a and 7b such that a gap 45 is formed between the portions 7a and 7b at a location corresponding to a portion where polarity of electric charge changes in electric charge distribution induced by driving the piezoelectric transformer 50D in the second-order width-extensional vibration mode. As shown in FIG. 17A, a first thickness portion 35a of the piezoelectric layers 35, which is disposed between one portion 7a of the first electrode layer 7 and the second electrode layer 47 below the one portion 7a, and a second thickness portion 35b of the piezoelectric layers 35, which is disposed between the other portion 7b of the first electrode layer 7 and the second electrode layer 47 below the other portion 7b, are polarized in opposite directions in the thickness direction, respectively. In the high-impedance portion 3, the piezoelectric layer 35 is interposed between an electrode layer 48 connected to the terminal c and electrode layers 8a and 8b connected to the terminal d as shown in FIG. 17A.

In this embodiment, at least each of the first electrode layers 7 is divided in the width direction into the two portions 7a and 7b such that the gap 45 is formed between the portions 7a and 7b at the location corresponding to the portion where polarity of electric charge changes in electric charge distribution induced by driving the piezoelectric transformer 50D in the second-order width-extensional vibration mode as shown in FIG. 17A.

When the piezoelectric transformer 50D is driven in the second-order width-extensional vibration mode, polarity of electric charge induced at the one portion 7a of the first electrode layer 7 is different from that induced at the other portion 7b of the first electrode layer 7 as shown in FIG. 17D. However, since the first thickness portion 35a of the piezoelectric layers 35, which is disposed between the one portion 7a of the first electrode layer 7 and the second electrode layer 47, and the second thickness portion 35b of the piezoelectric layers 35, which is disposed between the other portion 7b of the first electrode layer 7 and the second electrode layer 47, are polarized in opposite directions in the thickness direction as described above, phase is shifted through 180 degrees and thus, electric charge induced at the one portion 7a and electric charge induced at the other portion 7b do not cancel each other. Therefore, in the piezoelectric transformer 50D, a large electric charge can be handled without drop of efficiency.

### FIFTH EMBODIMENT

FIG. 19 is a perspective view of a piezoelectric transformer 50E according to a fifth embodiment of the present invention. The piezoelectric transformer 50E includes a piezoelectric transformer body 50′ acting as one of the piezoelectric transformers 50A to 50D of the first to fourth embodiments, for example, the piezoelectric transformer 50A of the first embodiment and a metallic rectangular plate 55 bonded to a whole of a lower face of the piezoelectric transformer body 50′.

For example, thicknesses of the piezoelectric transformer body 50′ and the metallic rectangular plate 55 are set such that a maximum stress of the piezoelectric transformer 50E is produced in the metallic rectangular plate 55. By the above described setting, since the maximum stress is produced in the rectangular plate 55 made of metal capable of withstanding a distortion larger than that of piezoelectric substance forming the piezoelectric transformer body 50′, the piezoelectric transformer 50E can be operated at an amplitude larger than that of the piezoelectric transformer made of piezoelectric substance only, namely, one of the piezoelectric transformers 50A to 50D of the first to fourth embodiments. As a result, the piezoelectric transformer 50E of this embodiment is capable of handling larger electric power.

Meanwhile, the metallic rectangular plate 55 is employed in this embodiment. However, the present invention is not limited to the metallic rectangular plate 55. If a material other than metal is capable of withstanding a distortion larger than that of the piezoelectric substance of the piezoelectric transformer body 50′, it is needless to say that the metallic rectangular plate 55 may be replaced by a rectangular plate made of the material.

### SIXTH EMBODIMENT

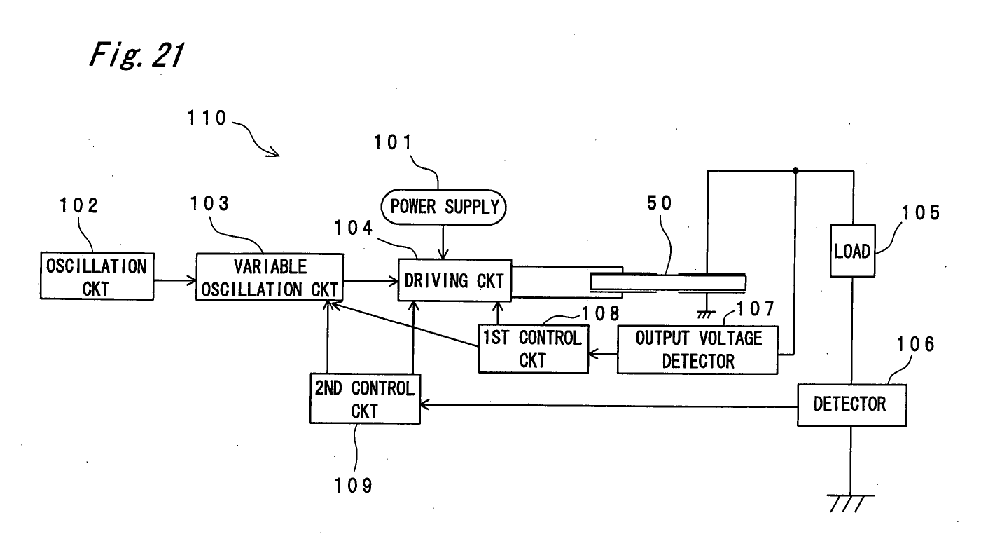

FIG. 20 is a sectional view of a piezoelectric transformer unit 100 according to a sixth embodiment of the present invention. The piezoelectric transformer unit 100 includes a piezoelectric transformer 50 and support members 40 for supporting the piezoelectric transformer 50, which are made of electrically conductive elastic material. The piezoelectric transformer 50 is formed by, for example, the piezoelectric transformer 50A of the first embodiment and is driven in the (λ/2) width-extensional vibration mode, i.e., the first-order mode. The support members 40 support the piezoelectric transformer 50 through their contact with the piezoelectric transformer 50 in the vicinity of the node of vibration at the time the piezoelectric transformer 50 is driven in the (λ/2) width-extensional vibration mode, i.e., the first-order mode. At points of contact of the support members 40 with the piezoelectric transformer 50, the support members 40 perform input-output operation of electric power in the piezoelectric transformer 50. The piezoelectric transformer 50 and the support members 40 are accommodated in a casing 41. The electrodes 7 and 9 are, respectively, electrically connected to the terminals a and b via the support members 40 by lead wires, while the electrodes 8 and 9 are, respectively, electrically connected to the terminals c and d via the support members 40.

In the piezoelectric transformer unit 100, since the support members 40 support the piezoelectric transformer 50 through their contact with the piezoelectric transformer 50 in the vicinity of the nod of vibration during drive of the piezoelectric transformer 50 in the (λ/2) width-extensional vibration mode, i.e., the first-order mode and perform input-output operation of electric power in the piezoelectric transformer 50 at the points of contact of the support members 40 with the piezoelectric transformer 50, support, clamp and electrical connection of the piezoelectric transformer 50 can be performed without hampering vibration, thereby resulting in rise of its reliability.

In this embodiment, the piezoelectric transformer 50 may also be formed by another piezoelectric transformer of the present invention, for example, the piezoelectric transformer 50C of the third embodiment. If the piezoelectric transformer 50C is supported in the vicinity of the node of vibration by the support members 40, the similar effects are gained.

### SEVENTH EMBODIMENT

FIG. 21 is a block diagram of a power supply circuit 110 according to a seventh embodiment of the present invention. In the power supply circuit 110, a piezoelectric transformer 50 which is formed by one of the piezoelectric transformers 50A to 50E of the first to fifth embodiments is used as a step-up circuit. The power supply circuit 110 includes a power supply 101, an oscillation circuit 102, a variable oscillation circuit 103, a driving circuit 104, a load 105, a detector 106, an output voltage detector 107, a first control circuit 108 and a second control circuit 109. In the power supply circuit 110, an input circuit for supplying an input power to the piezoelectric transformer 50 is constituted by the components 101 to 104, while an output circuit for picking up an output power from the piezoelectric transformer 50 is constituted by the components 105 to 109.

A frequency signal is generated by the variable oscillation circuit 103 and a drive signal of the piezoelectric transformer 50 is produced by the driving circuit 104. The piezoelectric transformer 50 is controlled on the basis of a detection signal of the detector 106 by the second control circuit 109 via the variable oscillation circuit 103 and the driving circuit 104 such that the piezoelectric transformer 50 can be stably driven in response to change of voltage applied to the load 105 connected to the electrodes of the generator portion of the piezoelectric transformer 50. In case the load 105 is a tube such as a cold cathode tube and a hot cathode tube, the voltage output detector 107 is operated until the tube is turned on. Thus, when electric current starts flowing through the tube, the output voltage detector 107 stops its operation. The first control circuit 108 controls output voltage such that the output voltage does not exceed a preset value.

In case the piezoelectric transformer 50 of the present invention is used for a step-up inverter circuit, it is possible to obtain a circuit having a circuit efficiency higher than that of a step-up circuit using an electromagnetic transformer because the driving efficiency of the piezoelectric transformer 50 is higher than that of the electromagnetic transformer. Meanwhile, since electrical energy handled by a unit volume of the piezoelectric transformer 50 of the present invention is larger than that of the electromagnetic transformer, volume of the piezoelectric transformer 50 can be reduced and the step-up circuit can be made thin by shape of the piezoelectric circuit 50. In addition, the piezoelectric transformer 50 utilizes the radial-extensional vibration mode and thus, is capable of handling large electric power.

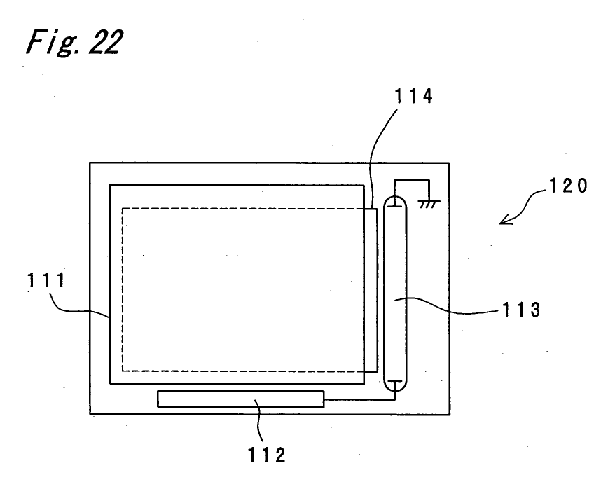

FIG. 22 shows a liquid crystal display 120 incorporating a cold cathode tube type lighting unit formed by the power supply circuit 110 of FIG. 21. The cold cathode tube type lighting unit is formed by a piezoelectric transformer inverter circuit 112 which is obtained by deleting the load 105 from the power supply circuit 110 of FIG. 20 and a cold cathode tube 113 acting as the load 105 of the power supply circuit 110 of FIG. 20. Thus, in this cold cathode tube type lighting unit, an input circuit for supplying an input power to the piezoelectric transformer 50 is constituted by the components 101 to 104 of the power supply circuit 110, while an output circuit for picking up an output power from the piezoelectric transformer 50 is constituted by the cold cathode tube 113 and the components 106 to 109 of the power supply circuit 110. In the liquid crystal display 120, a liquid crystal panel 111 is illuminated by the cold cathode tube type light unit of the above described arrangement through a light guide plate 114 provided at a back of the liquid crystal panel 111.

In the conventional electromagnetic transformer, a high voltage at the time of start of turning on of the cold cathode tube 113 should be outputted at all times. On the other hand, in the liquid crystal display 120, since the piezoelectric transformer 50 of the present invention is used, output voltage of the piezoelectric transformer 50 changes according to load variations at the time of start of turning on of the cold cathode tube 113 and during on-state period of the cold cathode tube 113, so that other circuits existing in the liquid crystal display 120 are not adversely affected by the load variations. Meanwhile, since output voltage applied to the cold cathode tube 113 from the piezoelectric transformer 50 in the piezoelectric transformer inverter circuit 112 has substantially sine wave, unnecessary frequency components which do not contribute to turning on of the cold cathode tube 113 are little in the output voltage and service life of the cold cathode tube 113 is lengthened.

### EIGHTH EMBODIMENT

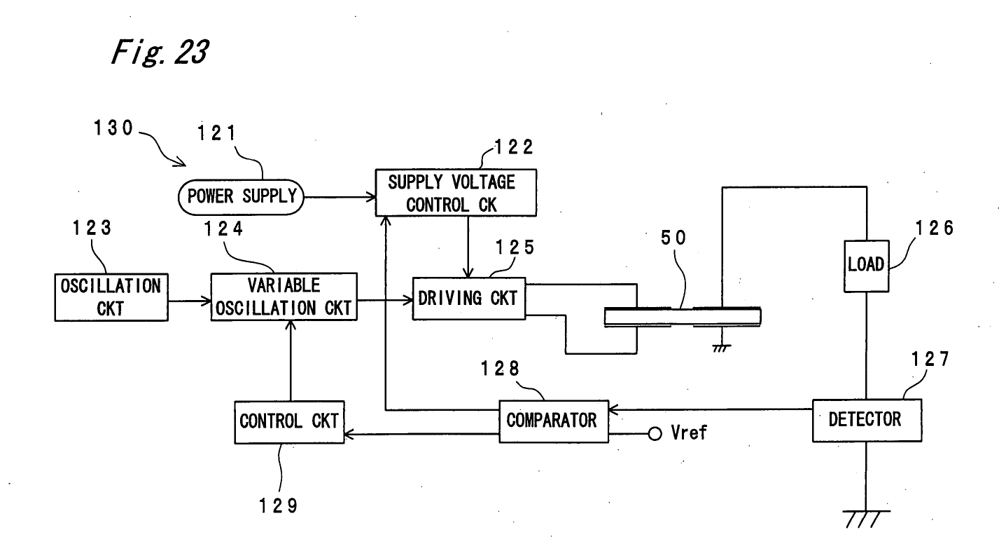

FIG. 23 is a block diagram of a power supply circuit 130 according to an eighth embodiment of the present invention. The power supply circuit 130 uses a piezoelectric transformer 50 formed by one of the piezoelectric transformers 50A to 50E of the first to fifth embodiments and includes a power supply 121, a supply voltage control circuit 122, an oscillation circuit 123, a variable oscillation circuit 124, a driving circuit 125, a load 126, a detector 127, a comparator 128 and a control circuit 129. A reference frequency is produced by the oscillation circuit 123. The comparator 128 compares an output from the detector 127 with a set voltage Vref so as to control one or both of a supply voltage for the supply voltage control circuit 122 and a driving frequency for the control circuit 129. In response to control of the driving frequency by the control circuit 129 and control of the supply voltage by the supply voltage control circuit 122, the driving circuit 125 performs power amplification for driving the piezoelectric transformer 50. Meanwhile, the driving circuit 125 is formed by a switching element and a filter circuit. The load 126 is, for example, a cathode discharge tube.

Since electrical energy handled by a unit volume of the piezoelectric transformer 50 of the present invention is larger than that of the electromagnetic transformer, volume of the piezoelectric transformer 50 can be reduced and the step-up circuit can be made thin by shape of the piezoelectric circuit 50. In addition, the piezoelectric transformer 50 utilizes the width-extensional vibration mode and thus, is capable of handling large electric power.

### NINTH EMBODIMENT

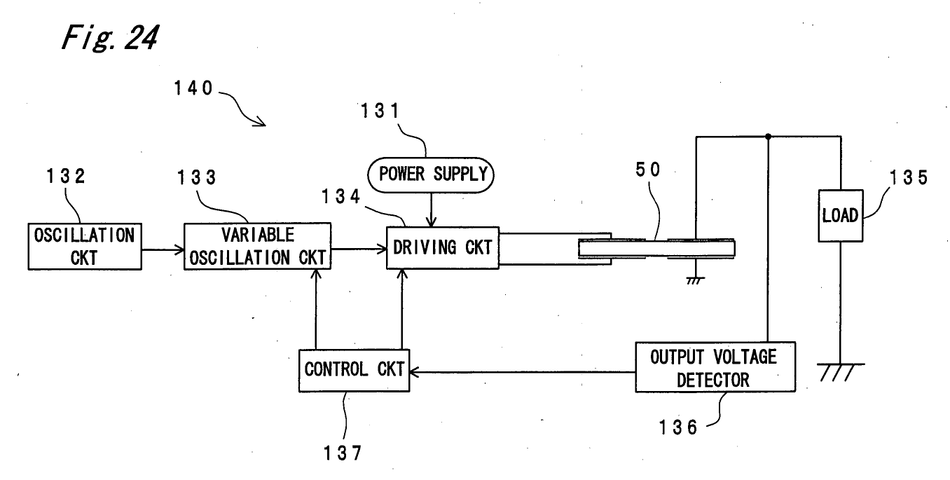

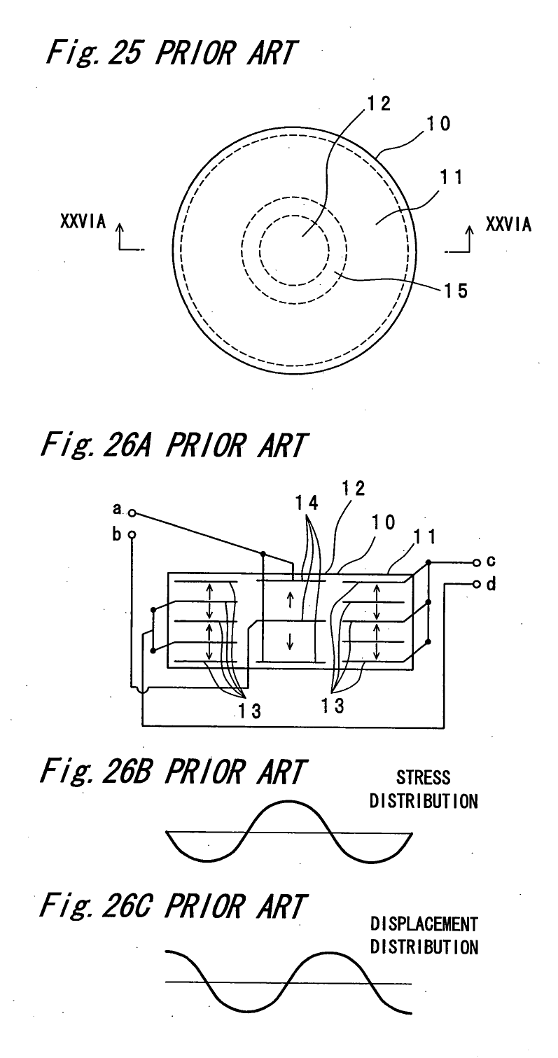

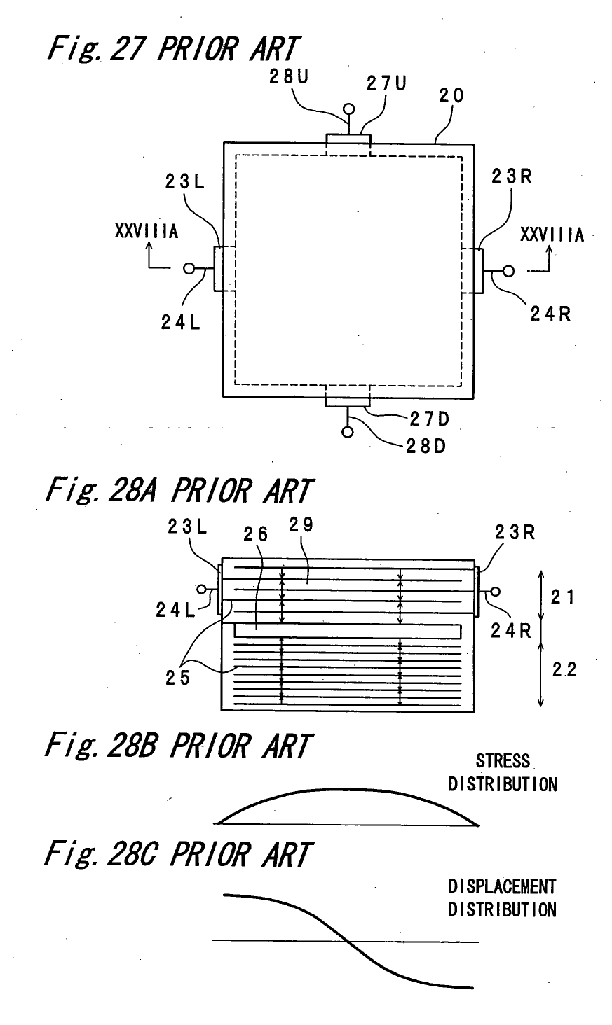

FIG. 24 is a block diagram of a power supply circuit 140 according to a ninth embodiment of the present invention. The power supply circuit 140 uses one of the piezoelectric transformers 50A to 50D of the first to fourth embodiments and includes a power supply 131, an oscillation circuit 132, a variable oscillation circuit 133, a driving circuit 134, a load 135, an output voltage detector 136 and a control circuit 137. The load 135 connected to the piezoelectric transformer 50 is formed by a rectifier circuit.

In this embodiment, output voltage, i.e., voltage applied to the load 135 can be controlled so as to be kept constant. Since electrical energy handled by a unit volume of the piezoelectric transformer 50 of the present invention is larger than that of the electromagnetic transformer, volume of the piezoelectric transformer 50 can be reduced and the piezoelectric transformer 50 can be made thin by its shape. In addition, the piezoelectric transformer 50 utilizes the width-extensional vibration mode and thus, is capable of handling large electric power.

As is clear from the foregoing description, the following marked effects are achieved in the present invention. Since the piezoelectric transformer of the present invention is driven in the width-extensional vibration mode, the effective electromechanical coupling factor higher than that of the lengthwise longitudinal vibration mode can be obtained. Therefore, since electric power handled by a unit volume of the piezoelectric transformer increases, output of the piezoelectric transformer can be raised.

In the power supply circuit and the lighting unit of the present invention, since the highly reliable piezoelectric transformer capable of yielding a large output is employed, the power supply circuit and the lighting unit can be made compact and are capable of handling a large electric power.

What is claimed is:

1. A piezoelectric transformer comprising:
a rectangular plate which is mainly made of piezoelectric material and in which a dimension in a longitudinal direction is larger than that in a width direction and a thickness direction is orthogonal to the longitudinal direction and the width direction; and
a low-impedance portion acting as one of a driving portion and a generator portion and a high-impedance portion acting as the other of the driving portion and the generator portion, which are provided in the rectangular plate so as to be arranged in the width direction;
wherein the piezoelectric transformer is adapted to be driven in a width-extensional vibration mode.

2. The piezoelectric transformer as claimed in claim 1, wherein the low-impedance portion includes first upper and second electrodes confronting each other through a first piezoelectric layer in the thickness direction and the high-impedance portion includes second upper and lower electrodes confronting each other through a second piezoelectric layer in the thickness direction.

3. The piezoelectric transformer as claimed in claim 1, wherein the low-impedance portion is formed by first electrode layers and first piezoelectric layers laminated on each other alternately in the thickness direction and the high-impedance portion is formed by second electrode layers and second piezoelectric layers laminated on each other alternately in the thickness direction.

4. The piezoelectric transformer as claimed in claim 1, wherein the rectangular plate is divided into first and second half regions arranged in the width direction;
wherein the low-impedance portion is provided in the first half region of the rectangular plate and the high-impedance portion is provided in the second half region of the rectangular plate such that the piezoelectric transformer is driven in a second-order width-extensional vibration mode.

5. A piezoelectric transformer comprising:
a rectangular plate which is mainly made of piezoelectric material and in which a dimension in a longitudinal direction is larger than that in a width direction and a thickness direction is orthogonal to the longitudinal direction and the width direction; and
a low-impedance portion acting as one of a driving portion and a generator portion and a high-impedance portion acting as the other of the driving portion and the generator portion, which are provided in the rectangular plate so as to be arranged in the thickness direction;
wherein the piezoelectric transformer is adapted to be driven in a width-extensional vibration mode.

6. The piezoelectric transformer as claimed in claim 5, further comprising:
an insulating portion for electrically separating the lower impedance portion and the high-impedance portion from each other, which is provided between the low-impedance portion and the high-impedance portion.

7. The piezoelectric transformer as claimed in claim 1, which is driven in a second-order width-extensional vibration mode,
wherein the low-impedance portion includes first and second electrode layers laminated on each other alternately in the thickness direction through piezoelectric layers and electrically connected to first and second terminals acting as an electric current input-output port and a further electric current input-output port of the low-impedance portion, respectively,
wherein at least each of the first electrode layers is divided in the width direction into two portions such that a gap is formed between the two portions at a location corresponding to a portion where polarity of electric charge changes in electric charge distribution induced by driving the piezoelectric transformer in the second-order width-extensional vibration mode,
wherein a first thickness portion of the piezoelectric layers, which is disposed between one of the two portions of each of the first electrode layers and each of the second electrode layers, and a second thickness portion of the piezoelectric layers, which is disposed between the other of the two portions of each of the first electrode layers and each of the second electrode layers, are polarized in opposite directions in the thickness direction, respectively.

8. The piezoelectric transformer as claimed in claim 1, wherein a ratio of the dimension in the longitudinal direction to that in the width direction in the rectangular plate ranges from 1.08 to 1.65.

9. The piezoelectric transformer as claimed in claim 1, further comprising:
a support member for supporting the piezoelectric transformer in the vicinity of a node of vibration at the time of drive of the piezoelectric transformer in the width-extensional vibration mode.

10. The piezoelectric transformer as claimed in claim 1, wherein electrical connection in the low-impedance portion and electrical connection in the high-impedance portion are performed in the vicinity of a node of vibration at the time of drive of the piezoelectric transformer in the width-extensional vibration mode.

11. The piezoelectric transformer as claimed in claim 1, further comprising:
a support member for supporting the piezoelectric transformer, which is made of electrically conductive elastic material;
wherein the support member is brought into contact with the piezoelectric transformer in the vicinity of a node of vibration at the time of drive of the piezoelectric transformer in the width-extensional vibration mode so as to support the piezoelectric transformer and performs electric power input-output operation in the piezoelectric transformer at a point of contact of the support member with the piezoelectric transformer.

12. The piezoelectric transformer as claimed in claim 1, further comprising:
a metallic rectangular plate which has a dimension substantially identical with that of the rectangular plate and is bonded to one of opposite faces of the rectangular plate in the thickness direction.

13. A power supply circuit comprising:
a piezoelectric transformer including a rectangular plate which is mainly made of piezoelectric material and in which a dimension in a longitudinal direction is larger than that in a width direction and a thickness direction is orthogonal to the longitudinal direction and the width direction and a low-impedance portion acting as one of a driving portion and a generator portion and a high-impedance portion acting as the other of the driving portion and the generator portion, which are provided in the rectangular plate so as to be arranged in the width direction such that the piezoelectric transformer is adapted to be driven in a width-extensional vibration mode;
an input circuit for supplying an input voltage to the piezoelectric transformer; and
an output circuit for picking up an output voltage from the piezoelectric transformer.

14. A power supply circuit comprising:
a piezoelectric transformer including a rectangular plate which is mainly made of piezoelectric material and in which a dimension in a longitudinal direction is larger than that in a width direction and a thickness direction is orthogonal to the longitudinal direction and the width direction and a low-impedance portion acting as one of a driving portion and a generator portion and a high-impedance portion acting as the other of the driving portion and the generator portion, which are provided in the rectangular plate so as to be arranged in the thickness direction such that the piezoelectric transformer is adapted to be driven in a width-extensional vibration mode;
an input circuit for supplying an input voltage to the piezoelectric transformer; and
an output circuit for picking up an output voltage from the piezoelectric transformer.

15. A lighting unit comprising:
a piezoelectric transformer including a rectangular plate which is mainly made of piezoelectric material and in which a dimension in a longitudinal direction is larger than that in a width direction and a thickness direction is orthogonal to the longitudinal direction and the width direction and a low-impedance portion acting as one of a driving portion and a generator portion and a high-impedance portion acting as the other of the driving portion and the generator portion, which are provided in the rectangular plate so as to be arranged in the width direction such that the piezoelectric transformer is adapted to be driven in a width-extensional vibration mode;
an input circuit for supplying an input voltage to the piezoelectric transformer; and
an output circuit for picking up an output voltage from the piezoelectric transformer.

16. A lighting unit comprising:
a piezoelectric transformer including a rectangular plate which is mainly made of piezoelectric material and in which a dimension in a longitudinal direction is larger than that in a width direction and a thickness direction is orthogonal to the longitudinal direction and the width direction and a low-impedance portion acting as one of a driving portion and a generator portion and a high-impedance portion acting as the other of the driving portion and the generator portion, which are provided in the rectangular plate so as to be arranged in the thickness direction such that the piezoelectric transformer is adapted to be driven in a width-extensional vibration mode;
an input circuit for supplying an input voltage to the piezoelectric transformer; and
an output circuit for picking up an output voltage from the piezoelectric transformer.
